(19) United States
(12) Patent Application Publication
(10) Pub. No.: US 2026/0223320 A1
(43) Pub. Date: Jul. 30, 2026

(54) COOLING DEVICE

(71) Applicants: DENSO CORPORATION, Kariya-city (JP); Sanyo-Onoda City Public University Corporation, Sanyo-Onoda City (JP)

(72) Inventors: Hitoshi YOSHIMURA, Kariya-city (JP); Takuro NAKAOKA, Kariya-city (JP); Syogo KATO, Kariya-city (JP); Kazuhisa YUKI, Yamaguchi (JP); Kohei YUKI, Yamaguchi (JP)

(73) Assignees: DENSO CORPORATION, Kariya-city (JP); Sanyo-Onoda City Public University Corporation, Sanyo-Onoda City (JP)

(21) Appl. No.: 19/460,691

(22) Filed: Jan. 27, 2026

(30) Foreign Application Priority Data
Jan. 27, 2025 (JP) 2025-011439

(51) Int. Cl. H05K 7/20

(52) U.S. Cl. CPC H05K 7/20254; H05K 7/20272

(57) ABSTRACT

The present disclosure provides a cooling device for cooling a heating element. The cooling device includes a heat transfer element and a cooler. The heat transfer element has a first surface as a mounting surface on which the heating element is mounted and a second surface as a surface opposite the first surface, in which a cooling surface for cooling the heating element is formed on the second surface. The cooler is configured to cool the heat transfer element using the coolant flowing within a flow path that is formed together with the second surface including the cooling surface. The cooling device is configured to form a pressure region that accelerates the inflow and outflow of the coolant within a cooling contribution region that contributes to cooling the cooling surface of the heat transfer element.

### CROSS-REFERENCE TO RELATED APPLICATION

This application is based on and claims the benefit of priority from earlier Japanese Patent Application No. 2025-011439, filed in Japan on January 27, 2025, the description of which is hereby incorporated by reference.

### BACKGROUND

### 1. Technical Field

The present disclosure relates to a cooling device.

### 2. Related Art

Some cooling devices cool a heating element by positioning a heat transfer element mounted thereon in thermal contact with a heat exchanger through which a coolant flows.

### SUMMARY

The present disclosure provides a cooling device. As an aspect of the technology of the present disclosure, a cooling device for cooling a heating element using a coolant includes a heat transfer element and a cooler. The heat transfer element has a first surface as a mounting surface on which the heating element is mounted and a second surface as a surface opposite the first surface, in which a cooling surface for cooling the heating element is formed on the second surface. The cooler is configured to cool the heat transfer element using the coolant flowing within a flow path that is formed together with the second surface including the cooling surface. The cooling device is configured to form a pressure region that accelerates the inflow and outflow of the coolant within a cooling contribution region that contributes to cooling the cooling surface of the heat transfer element.

### BRIEF DESCRIPTION OF THE DRAWINGS

In the accompanying drawings:

FIG. 1 is a schematic diagram illustrating the general configuration of a cooling system according to a first embodiment of the present disclosure;

FIG. 2 is a plane view of a cooling device according to the first embodiment of the present disclosure;

FIG. 3 is a cross-sectional view along line III-III in FIG. 2;

FIG. 4 is a cross-sectional view along line IV-IV in FIG. 2;

FIG. 5 is a side view showing a flow and a pressure region of the coolant in the cooling device;

FIG. 6 is a diagram illustrating heat transfer by a heat transfer element via a cooling contribution region, and the associated boiling bubbles.

FIG. 7 is a plane view of a cooling device according to a second embodiment of the present disclosure;

FIG. 8 is a cross-sectional view along line VIII-VIII in FIG. 7;

FIG. 9 is a cross-sectional view along line IX-IX in FIG. 7;

FIG. 10 is a side view showing a flow and a pressure region of the coolant in the cooling device;

FIG. 11 is a cross-sectional view of a cooling device according to a third embodiment of the present disclosure, corresponding to a position of a cross-section along line VIII-VIII in FIG. 7;

FIG. 12 is a cross-sectional view of the cooling device shown in FIG. 11, corresponding to a position of a cross-section along line IX-IX in FIG. 7;

FIG. 13 is a cross-sectional view of a cooling device according to a fourth embodiment of the present disclosure, corresponding to a cross-section along line VIII -VIII in FIG. 7;

FIG. 14 is a cross-sectional view of a cooling device shown in FIG. 13, corresponding to a cross-section along line IX-IX in FIG. 7;

FIG. 15 is a cross-sectional view along line XV-XV in FIG. 14;

FIG. 16 is an enlarged view of an area enclosed by dashed lines in FIG. 13;

FIG. 17 is a graph illustrating the relationship between a protrusion amount P of a protruding structure portion and a flow velocity in a fin channel;

FIG. 18 shows a centerline C1 corresponding to the position where the relationship illustrated in FIG. 17 was analyzed; and

FIG. 19 is an enlarged view of the vicinity of a cooling surface of a heat transfer element, described in a modification of the fourth embodiment.

### DETAILED DESCRIPTION OF THE PREFERRED EMBODIMENTS

For example, Japanese Patent Application Publication No. 2017-15269 (hereinafter referred to as Patent Document 1) discloses an evaporative-cooling device. The disclosed cooling device includes a boiling heat transfer member having a boiling heat transfer surface on which a plurality of holes and a plurality of annular protrusions are formed. Each hole has a rough inner circumferential surface. Each annular protrusion is formed around the opening of each hole. This enhances the cooling efficiency of the heating element. The annular protrusions are formed by molten metal droplets, which are generated by laser beam irradiation, scattering and adhering around the holes, subsequently solidifying and accumulating. Surfaces of the annular protrusions are rough. Having such annular protrusions increases a heat transfer area. Furthermore, boiling of the coolant occurs on the inner circumferential surface of the hole and the surfaces of the annular protrusions, which improves a bubble generation rate. As a result, the cooling efficiency of the heating element can be enhanced.

In recent years, the heat generation density tends to increase, for example, due to an increase in the number of heating elements accompanying enhanced functionality. Accordingly, in order to achieve further improvement in cooling performance, there is a method of refining the shape of the cooling surface to increase the surface area. However, the method of refining the cooling surface shape not only makes machining difficult, but also allows foreign matter in the coolant to enter gaps formed by annular protrusions or holes, resulting in blockage and reducing the cooling performance. In addition, burnout of the heating element may occur due to the coalescence of adjacent boiling bubbles on the cooling surface. Consequently, the cooling surface may dry out, which further reduces the cooling performance.

Note that we have described a case where the boiling heat transfer surface has irregularities, such as the annular protrusions. Even when no irregularities are formed, burnout may still occur due to the coalescence of adjacent bubbles, thus reducing the cooling performance.

The present disclosure aims to provide a cooling device that promotes the detachment and condensation of boiling bubbles occurring on a cooling surface, thereby improving cooling performance.

In a cooling device for cooling a heating element using a coolant according to a first aspect of the present disclosure, the device includes a heat transfer element and a cooler. The heat transfer element has a first surface as a mounting surface on which the heating element is mounted and a second surface as a surface opposite the first surface, in which a cooling surface for cooling the heating element is formed on the second surface. The cooler is configured to cool the heat transfer element using the coolant flowing within a flow path that is formed together with the second surface including the cooling surface. The cooling device is configured to form a pressure region that accelerates the inflow and outflow of the coolant within a cooling contribution region that contributes to cooling the cooling surface of the heat transfer element.

With this configuration, the cooling device of the present disclosure forms the pressure region within the flow path of the coolant that accelerates the inflow and outflow of the coolant in the cooling contribution region near the cooling surface of the heat transfer element. Therefore, the cooling device of the present disclosure can facilitate refining (i.e., size reduction) of boiling bubbles formed on the cooling surface of the heat transfer element. This enables this device to promote the detachment and condensation of boiling bubbles generated on the cooling surface of the heat transfer element, thereby improving cooling performance.

In a cooling device for cooling a heating element using a coolant according to a second aspect of the present disclosure, the device includes a heat transfer element and a cooler. The heat transfer element has a first surface as a mounting surface on

which the heating element is mounted and a second surface as a surface opposite the first surface, wherein a cooling surface for cooling the heating element is formed on the second surface. The cooler is configured to cool the heat transfer element using the coolant flowing within a flow path that is formed together with the second surface including the cooling surface. The cooling surface of the heat transfer element is included in a protruding structure portion. The protruding structure portion protrudes from the second surface into the flow path and is configured to change a flow direction of the coolant, on contact with the coolant, to a direction having a component in a normal direction perpendicular to the cooling surface.

With this configuration, the cooling device of the present disclosure may include the protruding structure portion, and the cooling surface of the heat transfer element is included in the protruding structure portion. Consequently, the cooling device of the present disclosure can accelerate the inflow and outflow of the coolant in the cooling contribution region near the cooling surface of the heat transfer element, thereby facilitating refining (i.e., size reduction) of boiling bubbles formed on the cooling surface of the heat transfer element. This enables this device to promote the detachment and condensation of boiling bubbles generated on the cooling surface of the heat transfer element, thereby improving cooling performance.

Hereinafter, embodiments of the present disclosure will be described with reference to the drawings. Note that, in the following description, including other embodiments, identical or equivalent parts across the embodiments are denoted by the same reference numerals.

### First Embodiment

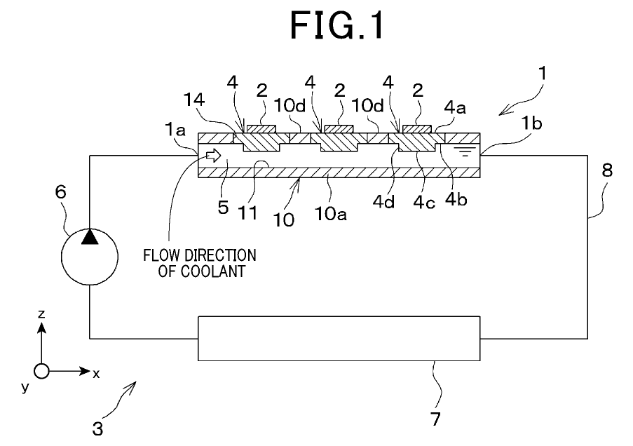

A first embodiment will now be described. An X-axis direction shown in the drawings indicates a flow direction of the coolant 5. A Y-axis direction indicates a normal direction perpendicular to a straight line along the X-axis direction. A Z-axis direction indicates a normal direction perpendicular to a mounting surface of a heating element within a heat transfer element. As shown in FIG. 1, a cooling device 1 is applied to a cooling system 3 for cooling a heating element 2. The heating element 2 is mounted on the cooling device 1 while disposed to a heat transfer element 4. Heat generated by the heating element 2 is transferred to the coolant 5 flowing inside the cooling device 1 via the heat transfer element 4. This cools the heating element 2. The heating element 2 to be cooled is a semiconductor device that generates heat when energized, such as a semiconductor switching element in a power conversion device in a vehicle. Examples of semiconductor switching elements include power MOSFETs (Metal-Oxide-Semiconductor Field-Effect Transistors), IGBTs (Insulated-Gate Bipolar Transistors), and the like.

The heat transfer element 4 electrically separates the heating element 2 from the coolant 5 and functions to transfer the heat generated by the heating element 2 to the coolant 5 while radiating the heat. The heat transfer element 4 only needs to be insulated between a first surface facing the heating element 2 and a second surface contacting the coolant 5. The heat transfer element 4 may be configured, for example, as an insulating substrate or as a multilayer laminated substrate.

First, the cooling system 3 that employs the cooling device 1 according to the first embodiment will be described. As shown in FIG. 1, the cooling system 3 includes components such as the cooling device 1, a pump 6, and a heat exchanger 7 (radiator). The cooling system 3 is configured by coupling the respective components to a piping 8 that circulates the coolant 5.

The coolant 5 circulated in the cooling system 3 is a subcooled liquid. A subcooled liquid is a liquid at a temperature lower than the saturation temperature at a given pressure. The coolant 5 may be, for example, water or an electrically insulating liquid, such as an LLC (Long Life Coolant) or a fluorinated inert liquid. The coolant 5 is pressure-regulated so that its boiling point is sufficiently lower than the average operating temperature of the heating element 2. The pump 6 sucks the coolant 5 from the piping 8 and discharges the sucked coolant 5 to supply it to the cooling device 1. This enables the cooling device 1 to cool the heating element 2. The heat exchanger 7 dissipates heat from the coolant 5, which has increased in temperature due to the cooling of the heating element 2 by the cooling device 1. The cooling system 3 is configured such that the coolant 5 flows through the piping 8 in the order of the pump 6, the cooling device 1, and the heat exchanger 7.

Configured as such, the cooling system 3 operates to cool the heating element 2 in the cooling device 1 using the coolant 5 supplied from the pump 6, and then cools the coolant 5, which has increased in temperature due to this cooling, using the radiator 7. By repeatedly performing the above operation, the cooling system 3 is capable of continuous cooling of the heating element 2 by the cooling device 1.

### Configuration of Cooling Device 1

Next, the details of the cooling device 1 according to the present embodiment will be described. As shown in FIG. 1, the cooling device 1 includes an inlet 1a through which the coolant 5 flows in and an outlet 1b through which the coolant 5 flows out, and is configured such that the coolant 5 flows through the interior of this device.

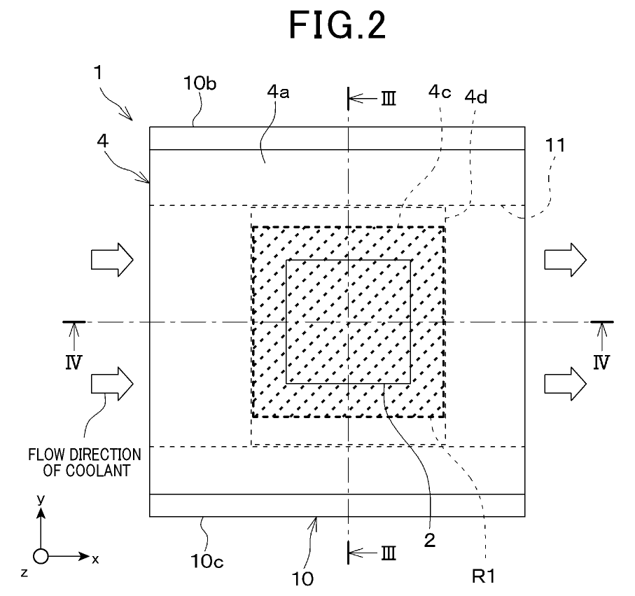

As shown in FIGS. 2 to 4, the cooling device 1 includes a cooler 10 that defines the outer shape of the cooling device 1. The cooler 10 has a flow path 11 formed therein, through which the coolant 5 flows. As shown in FIG. 4, the flow path 11 includes a narrow flow path 11a, an upstream flow path 11b, and a downstream flow path 11c. The narrow flow path 11a is the flow path where a cooling surface 4c of the heat transfer element 4 is located. The upstream flow path 11b is the flow path located upstream of the narrow flow path 11a. The downstream flow path 11c is the flow path located downstream of the narrow flow path 11a. In other words, the upstream flow path 11b is located closer to the inlet 1a of the flow path 11 than the narrow flow path 11a. The downstream flow path 11c is located closer to the outlet 1b of the flow path 11 than the narrow flow path 11a. Furthermore, as shown in FIG. 1, an opening 14 is formed in the cooler 10. The heat transfer element 4, to which the heating element 2 is disposed, is mounted in the cooler 10 at the position where the opening 14 is formed.

This allows the heat transfer element 4 to contact the coolant 5, enabling cooling of the heating element 2 by the coolant 5.

Note that, as shown in FIG. 1, the cooling device 1 may be configured to cool a plurality of heating elements 2. In that case, the flow path 11 is configured to have the narrow flow path 11a at each position where the heating element 2 is arranged, and to have the upstream flow path 11b and the downstream flow path 11c on the respective upstream and downstream sides of the narrow flow path 11a. Furthermore, in the configuration shown in FIG. 1, the plurality of heating elements 2 are arranged one by one along a longitudinal direction of the flow path 11; however, the present disclosure is not limited thereto. The longitudinal direction of the flow path 11 referred to here corresponds to the direction in which the coolant 5 flows from the upstream side to the downstream side of the flow path 11 (the flow direction of the coolant 5: X-axis direction). The plurality of heating elements 2 may alternatively be arranged one by one in a normal direction perpendicular to a straight line along the longitudinal direction of the flow path 11 (the normal direction: Y-axis direction). Furthermore, the structure is not limited to one heating element 2 per heat transfer element 4; it may also include a structure where a plurality of heating elements 2 are provided per heat transfer element 4.

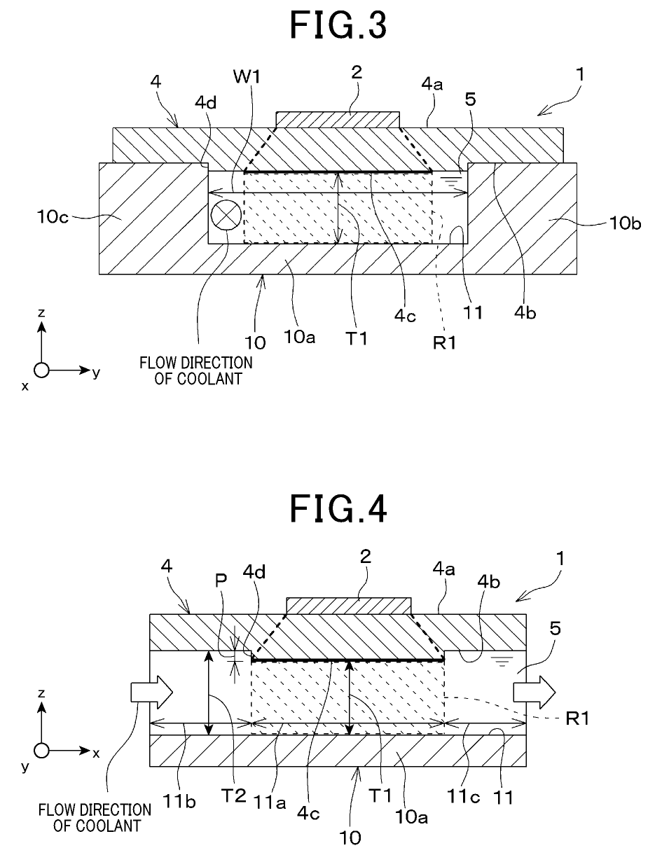

As shown in FIGS. 3 and 4, a cooling surface 4c is formed on a surface 4b (second surface) of the heat transfer element 4 opposite the mounting surface 4a (first surface) where the heating element 2 is arranged. The cooling surface 4c refers to a two-dimensional region (a region in the X-axis and Y-axis directions) on the surface where the heat transfer element 4 contacts the coolant 5, the region expanding at an angle θ of 45 degrees from the mounting surface 4a of the heating element 2 in the Z-axis direction. As shown in FIG. 2, if the heating element 2 is a quadrangular semiconductor element, the cooling surface 4c forms a quadrangular region, as indicated by a thick dashed line in the figure, which surrounds the heating element 2 and encloses the mounting area of the heating element 2. The angle at which the heat generated by the heating element 2 is radiated and transferred within the heat transfer element 4 varies depending on factors such as a flow velocity of the coolant 5. However, the angle at which the heat generated by the heating element 2 is transferred is generally around 45 degrees. Therefore, in the present embodiment, a region of the cooling surface 4c is defined as an angular range (45 degrees or less) within which the heat generated by the heating element 2 is transferred within the heat transfer element 4 at an interface between the heat transfer element 4 and the coolant 5. Note that, in FIGS. 3 and 4, for ease of understanding, the region of the cooling surface 4c is shown with a thick solid line and a heat transfer path is shown with a thick dashed line for convenience.

Furthermore, as shown in FIGS. 3 and 4, a protruding structure portion 4d is formed on the surface 4b of the heat transfer element 4 in a region including the cooling surface 4c. The protruding structure portion 4d is configured to protrude toward the flow path 11 more than toward the surrounding region (e.g., a region not including the cooling surface 4c). As a result, in the region where the protruding structure portion 4d is formed, the cross-sectional area of the flow path 11 in the Z-axis direction is reduced compared to the region where the protruding structure portion 4d is not formed, thereby constituting the narrow flow path 11a.

In the present embodiment, as shown in FIG. 3, the cooler 10 includes a first wall 10a, a second wall 10b, and a third wall 10c. The first wall 10a is a wall opposite the heat transfer element 4 and a fourth wall 10d across the flow path 11. The second wall 10b and the third wall 10c are connected to the first wall 10a and are positioned between the first wall 10a and the heat transfer element 4. The second wall 10b and the third wall 10c are walls opposite each other across the flow path 11. The flow path 11 is thus formed and enclosed by the first wall 10a to the third wall 10c and the heat transfer element 4. Furthermore, as shown in FIG. 1, on the side opposite the first wall 10a, the portion other than the heat transfer element 4 placement region is covered by the fourth wall 10d. In the following description, a direction in which the heat transfer element 4 (or the fourth wall 10d) and the first wall 10a are aligned, which is the normal direction perpendicular to a straight line along the flow direction (X-axis direction) of the coolant 5, is also referred to as a height direction (Z-axis direction) of the flow path 11. The direction perpendicular to the height direction is also referred to as a width direction (Y-axis direction) of the flow path 11. Furthermore, for example, in the narrow flow path 11a, a distance between the cooling surface 4c and the first wall 10a is referred to as a height dimension T1 of the flow path 11 (or simply the height dimension T1). A distance from the second wall 10b to the third wall 10c is referred to as a width dimension W1 of the flow path 11 (or simply the width dimension W1).

As shown in FIG. 3, the protruding structure portion 4d of the present embodiment is formed across the entire width dimension W1 of the flow path 11, that is, the distance from the second wall 10b to the third wall 10c. Therefore, in the protruding structure portion 4d, the cooling surface 4c is formed by an inner portion away from the second wall 10b and the third wall 10c. Furthermore, as shown in FIG. 4, the height dimension T1 (first dimension) of the narrow flow path 11a is smaller than the height dimension T2 (second dimension) of the upstream flow path 11b and the downstream flow path 11c due to the formation of the protruding structure portion 4d. A protrusion amount P of the protruding structure portion 4d from the surface 4b (the second surface) opposite the mounting surface 4a (the first surface) where the heating element 2 is placed may be set to an amount that achieves the operations and effects described later. For example, the protrusion amount P may be set such that the coolant 5 impinging on the protruding structure portion 4d changes its flow direction to a direction having a component in the normal direction perpendicular to the cooling surface 4c. The protrusion amount P may, for example, be in a range of tens to hundreds of micrometers (μm).

### Operations and Effects of Cooling Device 1

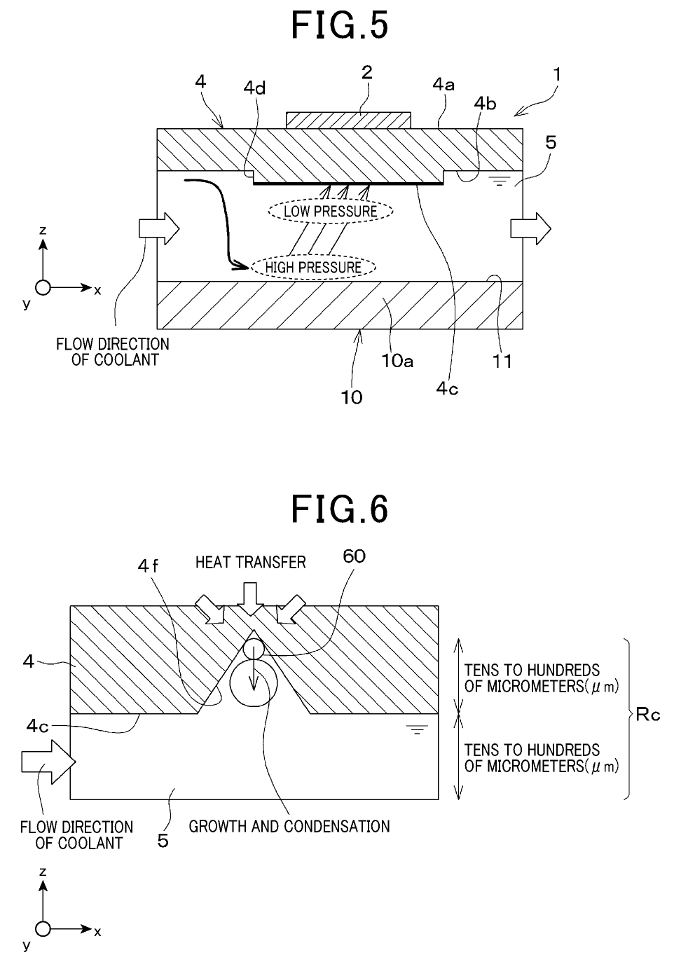

The operations and effects of the cooling device 1 of the present embodiment will now be described. In the cooling device 1 of the present embodiment, the protruding structure portion 4d is formed on the heat transfer element 4 in the region including the cooling surface 4c. Therefore, as indicated by a thick arrow in FIG. 5, the coolant 5 impinges on the protruding structure portion 4d, causing the flow direction of the coolant 5 to change. As a result, the coolant 5 flows toward the first wall 10a. This generates a centrifugal force effect on the flow within the narrow flow path 11a. Consequently, the narrow flow path 11a generates a high-pressure region where the pressure of the coolant 5 is higher in the direction from the cooling surface 4c toward the first wall 10a, compared to the upstream side of the flow path 11 (the upstream flow path 11b). Furthermore, the narrow flow path 11a generates a low-pressure region where the pressure of the coolant 5 is lower in the direction from the first wall 10a toward the region near the cooling surface 4c. Specifically, the coolant 5 flows from the high-pressure region toward a cooling contribution region Rc shown in FIG. 6 (described later), thereby generating the low-pressure region that has a lower pressure than the high-pressure region. Note that the cooling contribution region Rc refers to a region located near the cooling surface 4c where the coolant 5 can contribute to cooling the cooling surface 4c. Therefore, in the cooling device 1 of the present embodiment, the flow of the coolant 5 from the high-pressure region toward the low-pressure region is generated, thereby increasing a flow rate of the coolant 5 flowing into the cooling surface 4c. Furthermore, the flow rate of the coolant 5 that diffuses outward and flows out from the cooling surface 4c after reaching it also increases. Consequently, in the cooling device 1 of the present embodiment, the inflow and outflow of the coolant 5 to and from the cooling surface 4c can be accelerated.

Thus, the cooling device 1 of the present embodiment is configured such that the pressure region that accelerates the inflow and outflow of the coolant 5 within the cooling contribution region Rc near the cooling surface 4c is formed in the flow path 11. Specifically, the cooling device 1 of the present embodiment is configured to have the pressure region such that the pressure of the coolant 5 in a first region R1 (enclosed by dashed hatching in FIGS. 2 to 4) decreases in the direction from the first wall 10a toward the cooling surface 4c. That is, the coolant 5 in a region within the narrow flow path 11a, which is formed between the cooling surface 4c (the surface 4b) and the first wall 10a opposite the cooling surface 4c, has the pressure region such that the pressure decreases in the direction from the first wall 10a toward the cooling surface 4c. This accelerates the inflow of the coolant 5 toward the cooling surface 4c. Moreover, in the cooling device 1 of the present embodiment, accelerating the inflow and outflow of the coolant 5 in the cooling contribution region Rc near the cooling surface 4c facilitates refining (i.e., size reduction) of boiling bubbles formed on the cooling surface 4c. Furthermore, the detachment and condensation of boiling bubbles generated on the cooling surface 4c are promoted, thereby enabling improved cooling performance. In addition, the cooling device 1 of the present embodiment can suppress the phenomenon of burnout of the heating element that is caused by the coalescence of adjacent bubbles generated on the cooling surface 4c. Therefore, it is possible to further improve the cooling performance.

Note that the "cooling contribution region Rc near the cooling surface 4c" referred to herein is the region where the coolant 5 can contribute to cooling the cooling surface 4c, as described above. Specifically, the "cooling contribution region Rc near the cooling surface 4c" is a region expanding a fixed distance in the normal direction from the cooling surface 4c, as shown in FIG. 6. More specifically, the cooling contribution region Rc is a vicinity region within a distance range of tens to hundreds of micrometers (μm) from the cooling surface 4c. Therefore, the cooling contribution region Rc is the region within the coolant 5 that substantially contributes to cooling the cooling surface 4c. Within this cooling contribution region Rc, when boiling bubbles 60 form on the cooling surface 4c due to heat transfer from the heating element 2, they grow and condense. Therefore, to improve cooling performance, it is important to facilitate the detachment of the boiling bubbles 60 from the cooling surface 4c. Furthermore, when forming irregularities on the cooling surface 4c to facilitate the generation of the boiling bubbles 60, triangular groove portions 4f, as shown in FIG. 6, may be formed on the cooling surface 4c. When each groove portion 4f is formed on the cooling surface 4c, a depth-direction distance (an amount of the indentation) within the groove portion 4f, falling within a range of tens to hundreds of micrometers (μm), also corresponds to the cooling contribution region Rc.

### Second Embodiment

A second embodiment will now be described. The present embodiment modifies the configuration of the protruding structure portion 4d from that of the first embodiment. The remaining components of the present embodiment are the same as those of the first embodiment. Therefore, only components different from the first embodiment will be described in the present embodiment.

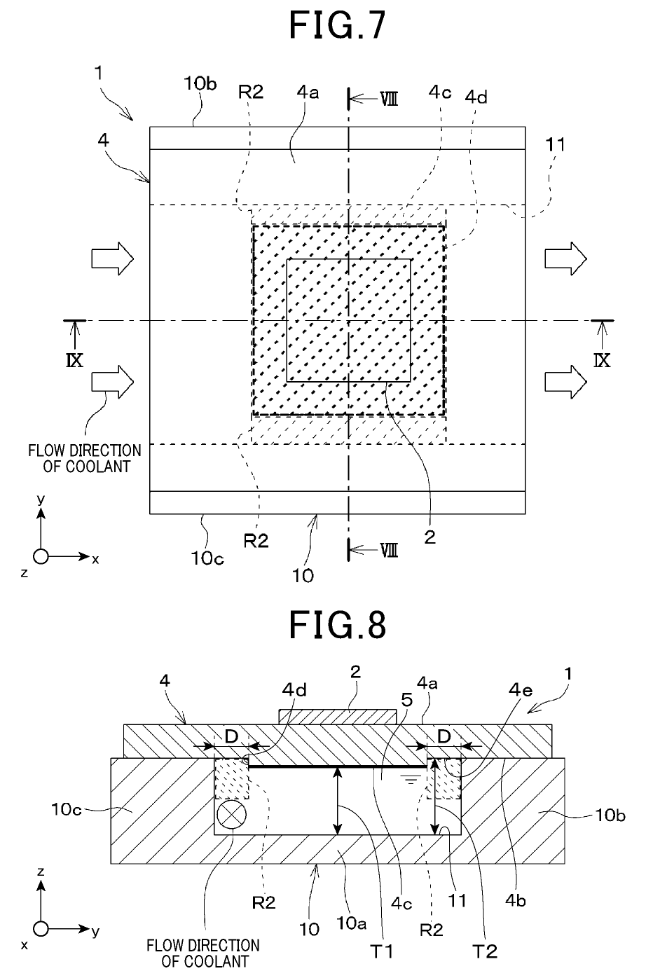

As shown in FIGS. 7 to 9, in the cooling device 1 of the present embodiment, the protruding structure portion 4d is formed separated from the second wall 10b and the third wall 10c by a predetermined distance D or greater. That is, in the present embodiment, the protruding structure portion 4d is not formed across the entire width dimension W1 of the flow path 11. Therefore, in the heat transfer element 4, a first portion located between the protruding structure portion 4d and the second wall 10b, and a second portion located between the protruding structure portion 4d and the third wall 10c, form first recesses 4e that are recessed more than the protruding structure portion 4d. That is, the heat transfer element 4 includes each first recess 4e, which are recessed more than the protruding structure portion 4d, on the outside of the protruding structure portion 4d in the normal direction perpendicular to the straight line along the flow direction of the coolant 5. The first recess 4e is exposed within the flow path 11. In the present embodiment, the first recess 4e is formed by a portion of the surface 4b (the second surface) opposite the mounting surface 4a (the first surface) where the heating element 2 is placed; however, the present disclosure is not limited thereto. The first recess 4e may also be configured to be further recessed than the surface 4b.

Here, a region hatched with dashed lines in FIGS. 7 to 9 is referred to as a second region R2. Specifically, the second region R2 corresponds to a half region (partial region) on the heat transfer element 4 side, in the height direction (the Z-axis direction), of the region between the first recess 4e and the first wall 10a. Furthermore, the main flow direction of the coolant 5 within the flow path 11 is the longitudinal direction (the X-axis direction) of the flow path 11. The first recess 4e and the second region R2 are positioned on both the left and right sides (both sides in the width direction) relative to a center axis in the longitudinal direction of the flow path 11. When referring to both sides in the width direction (the Y-axis direction) of the cooling surface 4c as lateral sides, the first recess 4e and the second region R2 are configured adjacent to the lateral sides of the cooling surface 4c.

When the first recess 4e is provided between the protruding structure portion 4d and the second wall 10b or between the protruding structure portion 4d and the third wall 10c, as configured in the present embodiment, the coolant 5 flows into the second region R2 side of the flow path 11. As a result, a high-speed flow of the coolant 5 occurs in a second region R2 of the flow path 11, as indicated by a thick arrow in FIG. 10. Consequently, a low-pressure region is formed in the cooling contribution region Rc (second cooling contribution region) near the first recess 4e, where the pressure is lower than in the cooling contribution region Rc (first cooling contribution region) outside the vicinity of the first recess 4e. In this way, when the coolant 5 flows out from the cooling surface 4c, the flow rate of the coolant 5 flowing out from the lateral sides can be increased. Consequently, in the cooling device 1 of the present embodiment, refining of the boiling bubbles 60 formed on the cooling surface 4c is further facilitated. Furthermore, the detachment and condensation of the boiling bubbles 60 generated on the cooling surface 4c are promoted, thereby enabling improved cooling performance similar to that of the first embodiment.

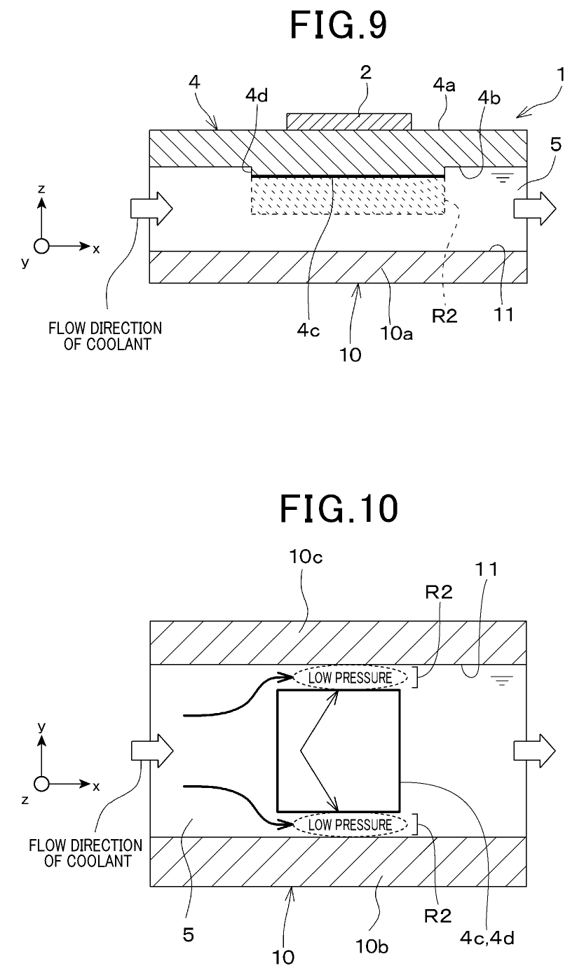

The structure of the present embodiment can also be applied even when the cooling device 1 cools a plurality of heating elements 2. When the plurality of heating elements 2 is arranged in a row along the longitudinal direction (the X-axis direction) of the flow path 11, the heat transfer element 4 disposed to each heating element 2 may have the cross-sectional structure shown in FIGS. 8 and 9. Alternatively, the plurality of heating elements 2 may be arranged one by one in the normal direction (the Y-axis direction) perpendicular to the longitudinal direction of the flow path 11. In that case, it is preferable that the outermost heating element 2 among the plurality of heating elements 2 be configured to include the first recess 4e, which is recessed more than the protruding structure portion 4d, between the cooling surface 4c and the second wall 10b or between the cooling surface 4c and the third wall 10c. Furthermore, it is also desirable to provide the first recess 4e between each cooling surface 4c.

### Third Embodiment

A third embodiment will now be described below. The present embodiment modifies the configuration of the first wall 10a from that of the first and second embodiments. The remaining components of the present embodiment are the same as those of the first and second embodiments. Therefore, only components different from the first and second embodiments will be described in the present embodiment. Hereinafter, an example of applying the present embodiment to the configuration of the second embodiment is provided.

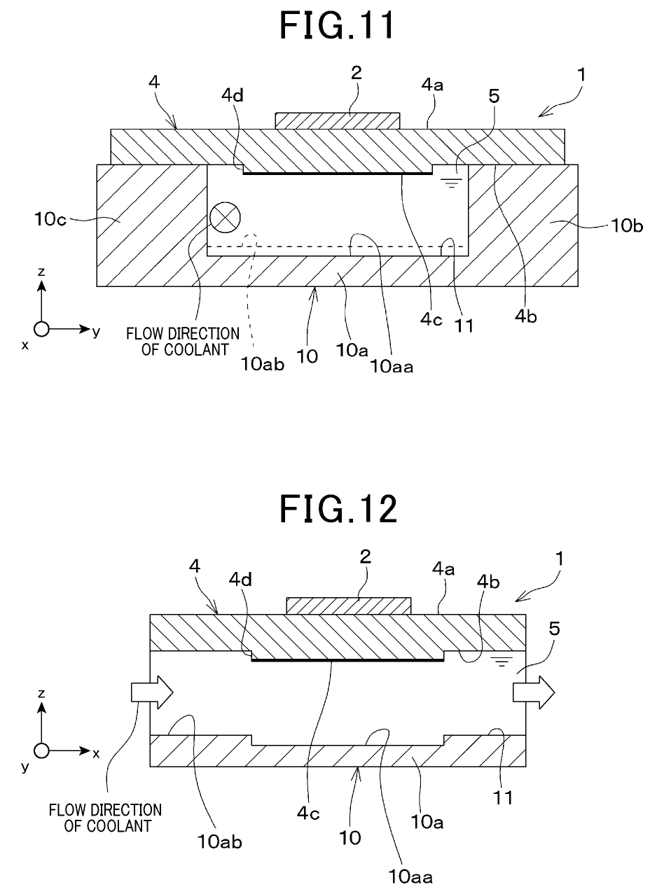

As shown in FIGS. 11 and 12, in the present embodiment, a second recess 10aa is formed in the first wall 10a at a position opposite the cooling surface 4c. The depth of the second recess 10aa can be any arbitrary value. In the present embodiment, for example, the depth-direction distance (the amount of the indentation) from a wall surface 10ab, which is the portion of the first wall 10a other than the second recess 10aa, is set to tens to hundreds of micrometers (μm).

As described in the first embodiment, the cooling device 1 of the present embodiment can also form a high-pressure region and a low-pressure region within the first region R1 of the narrow flow path 11a by providing the protruding structure portion 4d. Furthermore, in the configuration of the cooling device 1 of the present embodiment, which includes the second recess 10aa formed in the first wall 10a, the high-pressure region is formed at a position distant from the cooling surface 4c. As a result, the centrifugal force effect of the flow within the narrow flow path 11a is further enhanced in the cooling device 1 of the present embodiment. Therefore, the flow rate of the coolant 5 flowing into the cooling surface 4c can be further increased, enabling even higher cooling efficiency.

Note that, in the present embodiment, the second recess 10aa is formed at a position opposite the protruding structure portion 4d; however, the present disclosure is not limited thereto. The second recess 10aa may be formed at a position capable of forming a high-pressure region at a location at least distant from the cooling surface 4c. Therefore, the second recess 10aa need not be formed across the entire region of the first wall 10a at the position opposite the protruding structure portion 4d. The second recess 10aa may also be formed at a position offset from the position opposite the protruding structure portion 4d.

### Fourth Embodiment

A fourth embodiment will now be described below. The present embodiment modifies the configuration of the cooling surface 4c from that of the first to third embodiments. The remaining components of the present embodiment are the same as those of the first to third embodiments. Therefore, only components different from the first to third embodiments will be described in the present embodiment. Hereinafter, an example of applying the present embodiment to the configuration of the second embodiment is provided.

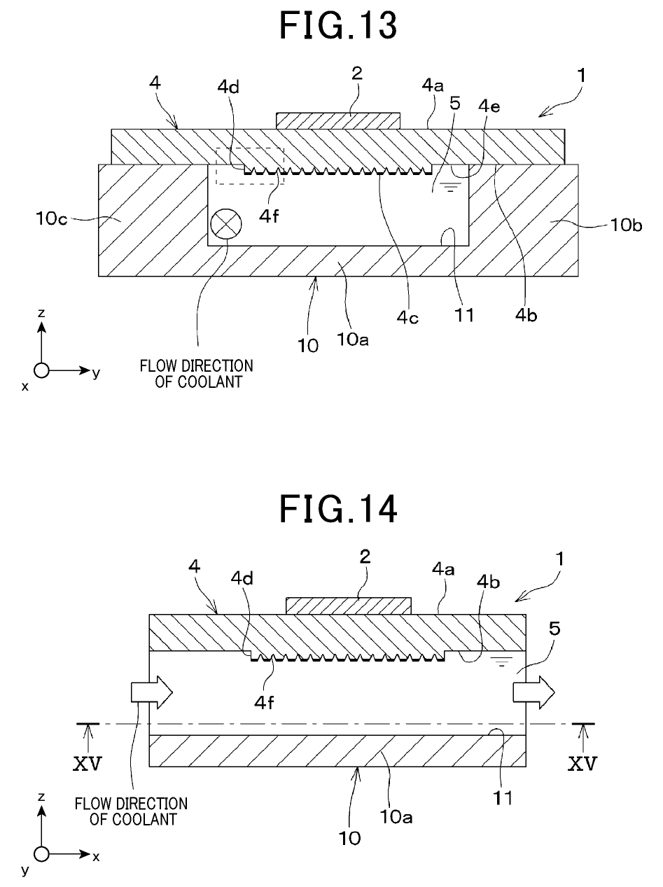

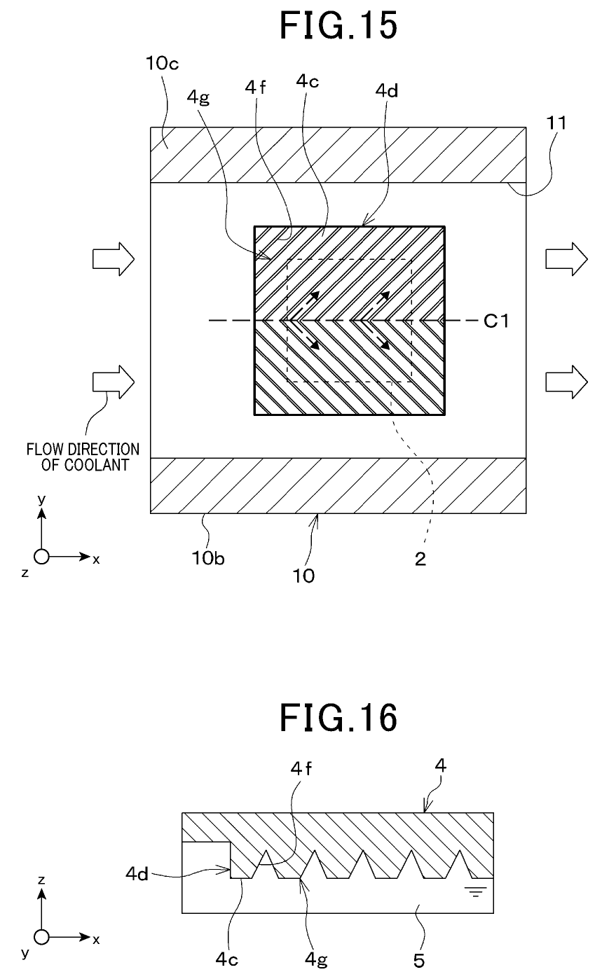

As shown in FIGS. 13 to 16, in the present embodiment, chevron-shaped convex fins 4g are formed by configuring the groove portions 4f on the cooling surface 4c. As shown in FIG. 14, each groove portion 4f corresponds to a V-shaped groove extending laterally from a central position of the cooling surface 4c in the width direction (the Y-axis direction) of the flow path 11. Furthermore, the plurality of V-shaped grooves is arranged in parallel along the longitudinal direction (the X-axis direction) of the flow path 11. Such V-shaped grooves, as shown in FIG. 16, define the convex fins 4g between two adjacent grooves.

In the structure having such convex fins 4g, the groove portion 4f functions as a fin channel and serves as the flow path for the coolant 5. Note that the fin channel is a type of structure designed to increase the heat transfer area for the fluid, thereby enhancing heat exchange. Even in the cooling device 1 of the present embodiment, as shown in FIG. 5, the centrifugal force effect caused by the flow of the coolant 5 toward the first wall 10a generates a high-pressure region near the first wall 10a and a low-pressure region in the cooling contribution region Rc near the cooling surface 4c. Therefore, the flow rate of the coolant 5 flowing into the cooling surface 4c increases. Consequently, the flow rate of the coolant 5 flowing into the fin channel also increases. As a result, the cooling device 1 of the present embodiment can facilitate refining of the boiling bubbles 60 generated within the fin channel. Furthermore, the detachment and condensation of the boiling bubbles 60 generated within the fin channel are promoted, thereby enabling improved cooling performance.

Moreover, in the cooling device 1 of the present embodiment, the fin channel extends from the center position of the cooling surface 4c to the lateral sides. Therefore, the coolant 5 that has flowed into the fin channel is easily guided toward the lateral sides of the cooling surface 4c by the groove portion 4f. As a result, the flow rate of the coolant 5 flowing out from the fin channel can be further increased. Therefore, in the cooling device 1 of the present embodiment, refining of the boiling bubbles 60 can be further facilitated, and the detachment and condensation of the boiling bubbles 60 generated within the fin channel are promoted, thereby further improving cooling performance.

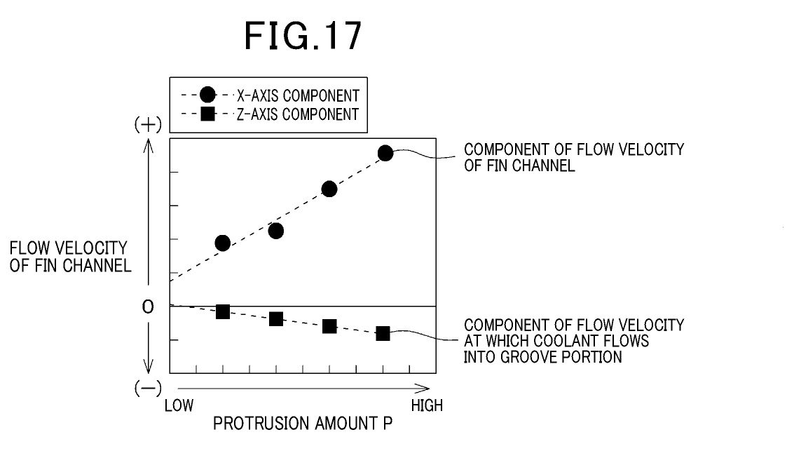

The flow velocity in the fin channel was measured relative to the protrusion amount P of the protruding structure portion 4d. In other words, the flow velocity of the coolant 5 within the fin channel was measured in a height range (a height range of the convex fin 4g) from a bottom of the groove portion 4f to an apex of the convex fin 4g (the inlet of the groove portion 4f). FIG. 17 shows an example of the measurement results. Note that the flow velocity in the fin channel represents the flow velocity of an X-axis component (flow direction component) and a Z-axis component (a height direction component) along a centerline C1 passing through the width center of the cooling surface 4c shown in FIG. 18. The X-axis component represents the flow velocity of the coolant 5 in a direction from the upstream side toward the downstream side of the flow path 11. The Z-axis component represents the flow velocity of the coolant 5 in a direction from the inlet of the groove portion 4f toward the bottom. That is, the Z-axis component represents the flow velocity at which the coolant 5 flows into the groove portion 4f.

A horizontal axis of FIG. 17 represents the protrusion amount P (the height of the convex fin 4g) of the protruding structure portion 4d. A larger value of the protrusion amount P indicates a greater height of the convex fin 4g. The vertical axis of FIG. 17 represents the flow velocity in the fin channel. As described above, the flow velocity has the X-axis component and the Z-axis component. A larger positive value of the X-axis component indicates a faster flow velocity of the coolant 5 in the direction from the upstream side toward the downstream side of the flow path 11. A larger negative value of the Z-axis component indicates a faster flow velocity of the coolant 5 in the direction from the inlet of the groove portion 4f toward the bottom. As shown in FIG. 17, even when the protrusion amount P of the protruding structure portion 4d is small, both the X-axis and Z-axis components of the flow velocity in the fin channel are generated. As the protrusion amount P of the protruding structure portion 4d increases (as the height of the convex fin 4g increases), the X-axis component of the flow velocity in the fin channel increases in the positive direction, and the Z-axis component increases in the negative direction. The increase in the X-axis component in the positive direction indicates that the pressure region formed in the narrow flow path 11a increases the flow rate of the coolant 5 in the fin channel. Furthermore, it indicates that the inflow and outflow of the coolant 5 from the lateral sides of the cooling surface 4c increase due to the low-pressure region generated on those sides.

Moreover, the increase in the Z-axis component in the negative direction indicates that the flow rate of the coolant 5 from the inlet toward the bottom of the groove portion 4f is increasing. Therefore, the measurement results shown in FIG. 17 verify that the cooling device 1 of the present embodiment achieves the effects described above. In the cooling device 1 of the present embodiment, increasing the protrusion amount P of the protruding structure portion 4d (increasing the height of the convex fin 4g) further enhances the centrifugal force effect of the flow in the narrow flow path 11a, thereby more effectively achieving the aforementioned effects.

Note that in the present embodiment, as shown in FIG. 18, measurement points are provided along the centerline C1 passing through a width center of the cooling surface 4c, and the flow velocity of the coolant 5 is measured in the respective axial directions of the X-axis and the Z-axis at the measurement points. Regarding the X-axis component, since the groove portion 4f is configured as the V-shaped groove, two flows in opposite directions occur on both sides of the centerline C1. Therefore, the flow velocity on the centerline C1 in the X-axis component is theoretically zero because the flow velocities of the two opposing flows cancel each other out. Accordingly, its representation is omitted in FIG. 17. However, in practice, a flow velocity in the X-axis component is actually generated on both sides of the centerline C1. Consequently, a result is obtained where the flow velocity in the X-axis component on the centerline C1 increases as the protrusion amount P of the protruding structure portion 4d increases.

### Modification of the Fourth Embodiment

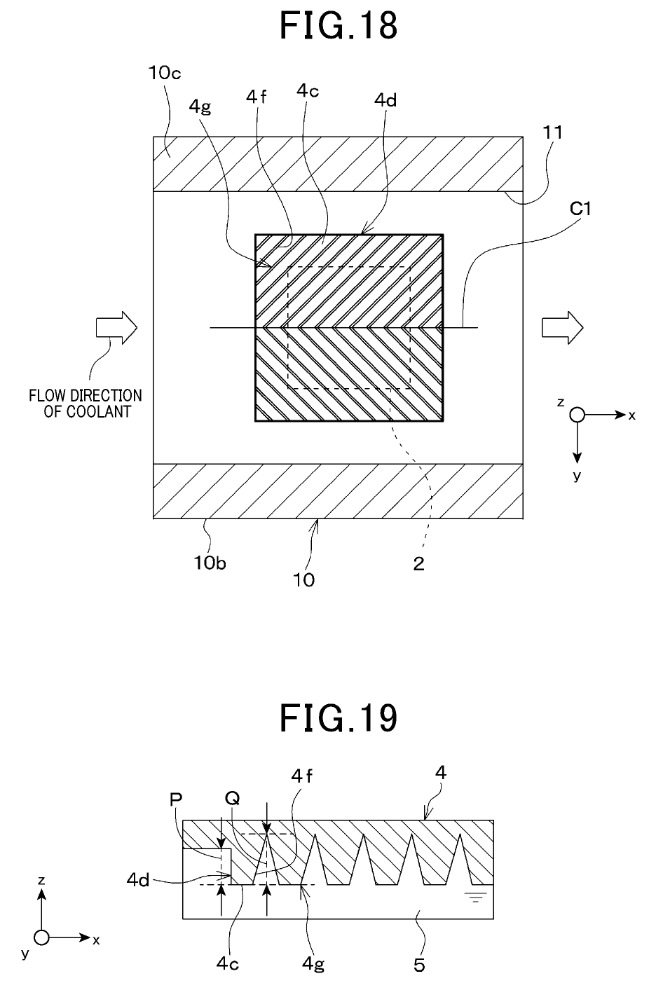

In the fourth embodiment described above, as shown in FIG. 16, the depth of the groove portion 4f (the height of the convex fin 4g) and the protrusion amount P of the protruding structure portion 4d are substantially the same; however, the present disclosure is not limited thereto. The depth of the groove portion 4f may be any arbitrary value. For example, as shown in FIG. 19, the groove portion 4f may be configured such that the depth Q (distance Q) thereof is greater than the protrusion amount P of the protruding structure portion 4d. Furthermore, the depth Q of each groove portion 4f need not be uniform among the plurality of groove portions 4f. For example, a configuration may be such that the depth Q of the groove portion 4f gradually decreases (i.e., the height of the convex fin 4g gradually decreases) as the distance from the centerline C1 increases. The depth Q of the groove portion 4f is preferably configured to be the same as the amount of indentation of the first recess 4e. Alternatively, the depth Q of the groove portion 4f is preferably configured to be smaller than the amount of indentation of the first recess 4e.

### Other Embodiments

Although the present disclosure has been described in accordance with the embodiments, it is to be understood that the disclosure is not limited to the embodiments. The technology of the present disclosure can be modified in various ways without departing from the scope of the disclosure. Furthermore, the elements shown in the above embodiments can be arbitrarily combined with each other.

That is, the above embodiments are not technically unrelated to each other. Unless a combination is clearly impossible, the above embodiments can be appropriately combined with each other. Furthermore, it is understood that the elements shown in the embodiments are not essential unless explicitly stated as such or unless they are clearly essential in principle. In addition, when the number of components or a numerical range of physical quantities is indicated, the number or range is not limited to a specific value unless a particular number is explicitly stated or clearly limited in principle. Furthermore, when the shape or relative position of components is indicated, the shape or position is not limited to a particular shape or position unless a specific shape or position is explicitly stated or clearly limited in principle.

For example, the shape of the protruding structure portion 4d is not limited to a quadrangular shape. The protruding structure portion 4d may have any arbitrary shape as long as it is configured to form the pressure region within the narrow flow path 11a that changes the flow direction of the coolant 5 and accelerates the inflow and outflow of the coolant 5 within the cooling contribution region Rc near the cooling surface 4c. Specifically, the protruding structure portion 4d may be configured to include a wall surface that, when positioned on the upstream side, can change the approaching flow of the coolant 5 into a flow having a component in the normal direction of the cooling surface 4c to generate the pressure region. For example, in FIG. 4, a wall surface of the protruding structure portion 4d is a vertical surface standing perpendicular to the surface 4b opposite the mounting surface 4a; however, the present disclosure is not limited thereto. For example, the wall surface of the protruding structure portion 4d may be an inclined surface slanted relative to the surface 4b. Furthermore, as in the fourth embodiment, even if the heat transfer element 4 includes convex fins 4g formed by the groove portions 4f in the protruding structure portion 4d, it is sufficient if the protruding structure portion 4d has a wall surface capable of generating the pressure region. With this configuration, the flow direction of the coolant 5 can be changed to form the aforementioned pressure region. Therefore, the groove portion 4f may be configured to be connected to the wall surface of the protruding structure portion 4d. Furthermore, the fins may have any arbitrary shape. However, in a structure lacking the wall surface of the protruding structure portion 4d, such as a configuration having holes and annular raised portions formed therearound as disclosed in Patent Document 1, it is impossible to change the flow direction of the coolant 5 to form the aforementioned pressure region. The same applies to a structure equipped with simple rod-shaped fins.

Furthermore, a surface of the fourth wall 10d of the cooler 10 on the flow path 11 side may be configured to be coplanar with the surface 4b of the heat transfer element 4, excluding the protruding structure portion 4d (i.e., the surface 4b in contact with the second wall 10b and the third wall 10c). In addition, a surface of the fourth wall 10d on the flow path 11 side may protrude from or be recessed relative to the surface 4b. In either configuration, a protrusion amount of the fourth wall 10d and a distance from the fourth wall 10d to the protruding structure portion 4d can be set such that the coolant 5 impinges on the protruding structure portion 4d located downstream of the fourth wall 10d to change the flow.

### Aspect of Present Disclosure

As is apparent from the description of the embodiments and modifications described above, at least the following aspects are disclosed herein.

### Aspect 1-1

A cooling device for cooling a heating element using a coolant, including:

a heat transfer element having a first surface as a mounting surface on which the heating element is mounted and a second surface as a surface opposite the first surface, in which a cooling surface for cooling the heating element is formed on the second surface; and a cooler that is configured to cool the heat transfer element using the coolant flowing within a flow path that is formed together with the second surface including the cooling surface, in which, the cooling device is further configured to form a pressure region that accelerates the inflow and outflow of the coolant within a cooling contribution region that contributes to cooling the cooling surface of the heat transfer element.

### Aspect 1-2

The cooling device according to Aspect 1-1, in which the cooler has a first wall facing the heat transfer element, and the cooling device is configured such that the coolant in a first region between the second surface and the first wall forms a high-pressure region in a direction from the second surface toward the first wall, and forms a low-pressure region with lower pressure than the high-pressure region in a direction from the high-pressure region toward the cooling contribution region.

### Aspect 1-3

The cooling device according to Aspect 1-2, in which the cooler further has a second wall and a third wall facing each other across the flow path, the second wall and the third wall are connected to the first wall, are disposed between the first wall and the heat transfer element, and in a case where a partial region on the heat transfer element side of a region between first and second portions and the first wall is defined as a second region, the first portion being located between the cooling surface of the heat transfer element and a second wall and the second portion being located between the cooling surface of the heat transfer element, the cooling device is configured such that, by having the coolant flow through the second region, the low-pressure region is formed in the cooling contribution region near the second region, where the pressure is lower than in the cooling contribution region outside the vicinity of the second region.

### Aspect 1-4

The cooling device according to any one of Aspects 1-1 to 1-3, in which the heat transfer element further has a protruding structure portion protruding from the second surface into the flow path, and the protruding structure portion includes the cooling surface and is configured to change a flow direction of the coolant, on contact with the coolant, to a direction having a component in a normal direction perpendicular to the cooling surface.

### Aspect 1-5

The cooling device according to Aspect 1-4, in which the heat transfer element further has a first recess on the outside of the protruding structure portion, which is recessed relative to the protruding structure portion, in a normal direction perpendicular to a straight line along the flow direction of the coolant, and in the dimension of the cooling surface in the normal direction within the flow path, a dimension at a position of the first recess is greater than a dimension at a position of the protruding structure portion.

### Aspect 1-6

The cooling device according to any one of Aspects 1-1 to 1-5, in which the cooler has a first wall facing the heat transfer element, and a second recess is formed in the first wall at a position facing the cooling surface.

### Aspect 1-7

The cooling device according to any one of Aspects 1-1 to 1-6, in which where a direction perpendicular to a longitudinal direction of the flow path and the normal direction of the cooling surface is defined as a width direction of the flow path, and where both sides of the cooling surface in the width direction are defined as lateral sides, a groove portion is formed on the cooling surface, the groove portion being configured by a V-shaped groove extending from a central position of the cooling surface toward the lateral sides in the width direction as the flow of the coolant proceeds from upstream to downstream, and the cooling surface is further provided with a convex fin formed by an adjacent pair of the grooves.

### Aspect 1-8

The cooling device according to Aspect 1-7, in which a depth of the groove portion is greater than a distance from the second surface to an apex of the convex fin.

### Aspect 2-1

A cooling device for cooling a heating element using a coolant, including: a heat transfer element having a first surface as a mounting surface on which the heating element is mounted and a second surface as a surface opposite the first surface, in which a cooling surface for cooling the heating element is formed on the second surface; and a cooler that is configured to cool the heat transfer element using the coolant flowing within a flow path that is formed together with the second surface including the cooling surface, in which, the heat transfer element further has a protruding structure portion protruding from the second surface into the flow path, and the protruding structure portion includes the cooling surface and is configured to change a flow direction of the coolant, on contact with the coolant, to a direction having a component in a normal direction perpendicular to the cooling surface.

What is claimed is:

1. A cooling device for cooling a heating element using a coolant, comprising:
a heat transfer element having a first surface as a mounting surface on which the heating element is mounted and a second surface as a surface opposite the first surface, in which a cooling surface for cooling the heating element is formed on the second surface; and
a cooler that is configured to cool the heat transfer element using the coolant flowing within a flow path that is formed together with the second surface including the cooling surface,
wherein,
the cooling device is further configured to form a pressure region that accelerates the inflow and outflow of the coolant within a cooling contribution region that contributes to cooling the cooling surface of the heat transfer element.

2. The cooling device according to claim 1, wherein
the cooler has a first wall facing the heat transfer element, and
the cooling device is configured such that the coolant in a first region between the second surface and the first wall forms a high-pressure region in a direction from the second surface toward the first wall, and forms a low-pressure region with lower pressure than the high-pressure region in a direction from the high-pressure region toward the cooling contribution region.

3. The cooling device according to claim 2, wherein
the cooler further has a second wall and a third wall facing each other across the flow path,
the second wall and the third wall are connected to the first wall, are disposed between the first wall and the heat transfer element, and
in a case where a partial region on the heat transfer element side of a region between first and second portions and the first wall is defined as a second region, the first portion being located between the cooling surface of the heat transfer element and a second wall and the second portion being located between the cooling surface of the heat transfer element,
the cooling device is configured such that, by having the coolant flow through the second region, the low-pressure region is formed in the cooling contribution region near the second region, where the pressure is lower than in the cooling contribution region outside the vicinity of the second region.

4. The cooling device according to claim 1, wherein
the heat transfer element further has a protruding structure portion protruding from the second surface into the flow path, and
the protruding structure portion includes the cooling surface and is configured to change a flow direction of the coolant, on contact with the coolant, to a direction having a component in a normal direction perpendicular to the cooling surface.

5. The cooling device according to claim 4, wherein
the heat transfer element further has a first recess on the outside of the protruding structure portion, which is recessed relative to the protruding structure portion, in a normal direction perpendicular to a straight line along the flow direction of the coolant, and
in the dimension of the cooling surface in the normal direction within the flow path, a dimension at a position of the first recess is greater than a dimension at a position of the protruding structure portion.

6. The cooling device according to claim 4, wherein
the cooler has a first wall facing the heat transfer element, and
a second recess is formed in the first wall at a position facing the cooling surface.

7. The cooling device according to claim 4, wherein
where a direction perpendicular to a longitudinal direction of the flow path and the normal direction of the cooling surface is defined as a width direction of the flow path, and where both sides of the cooling surface in the width direction are defined as lateral sides,
a groove portion is formed on the cooling surface, the groove portion being configured by a V-shaped groove extending from a central position of the cooling surface toward the lateral sides in the width direction as the flow of the coolant proceeds from upstream to downstream, and
the cooling surface is further provided with a convex fin formed by an adjacent pair of the grooves.

8. The cooling device according to claim 7, wherein
a depth of the groove portion is greater than a distance from the second surface to an apex of the convex fin.

9. A cooling device for cooling a heating element using a coolant, comprising:
a heat transfer element having a first surface as a mounting surface on which the heating element is mounted and a second surface as a surface opposite the first surface, in which a cooling surface for cooling the heating element is formed on the second surface; and
a cooler that is configured to cool the heat transfer element using the coolant flowing within a flow path that is formed together with the second surface including the cooling surface,
wherein,
the heat transfer element further has a protruding structure portion protruding from the second surface into the flow path, and
the protruding structure portion includes the cooling surface and is configured to change a flow direction of the coolant, on contact with the coolant, to a direction having a component in a normal direction perpendicular to the cooling surface.
